(19) United States
(12) Patent Application Publication
(10) Pub. No.: US 2026/0096189 A1
(43) Pub. Date: Apr. 2, 2026

(54) FIELD EFFECT DEVICE WITH ONE OR MORE RINGS AND ASSOCIATED METALLIZATION LAYERS

(71) Applicant: TEXAS INSTRUMENTS INCORPORATED, Dallas, TX (US)

(72) Inventors: Krishna Praveen Mysore Rajagopal, Manteca, CA (US); Rahul Prakash, Bangalore (IN); Shubham Panjrath, Bangalore (IN); Prathamesh Shanbhag, Dharwad (IN)

(21) Appl. No.: 19/194,522

(22) Filed: Apr. 30, 2025

Related U.S. Application Data
(60) Provisional application No. 63/700,028, filed on Sep. 27, 2024.
(60) Provisional application No. 63/700,036, filed on Sep. 27, 2024.

(51) Int. Cl. H10D 84/80; H01L 23/535; H10D 10/60; H10D 89/60

(52) U.S. Cl. CPC H10D 84/811; H10D 10/60; H10D 89/611; H10D 89/711; H10W 20/20

(57) ABSTRACT

Semiconductor devices, integrated circuits containing such semiconductor devices, and related methods are described. For example, a semiconductor device includes a field effect transistor comprising a gate and source and drain regions, wherein the source and drain regions extend parallel to one another in a first direction. The semiconductor device further includes a first metallization layer including first source and drain metal lines extending parallel to one another in the first direction, and a second metallization layer including second source and drain metal lines connected to the respective first source and drain metal lines. The second source and drain metal lines comprise a set of source metal lines that extend outward from an additional source metal line that extends in a second direction perpendicular to the first direction, and a set of drain metal lines that extend outward from an additional drain metal line that extends in the second direction.

### CROSS-REFERENCE TO RELATED APPLICATIONS

The present application claims priority to U.S. Provisional Patent Application Ser. No. 63/700,028, filed Sep. 27, 2024, and entitled “ESD Protection for High Speed Push-Pull Output Buffer in a Low Cost Chip,” and U.S. Provisional Patent Application Ser. No. 63/700,036, filed Sep. 27, 2024, and entitled “ESD Metallization Design for High Speed Push-Pull Output Buffer in a Low Cost Chip,” each of which is hereby incorporated by reference herein in its entirety. The present application is also related to co-pending U.S. Patent Application Attorney Docket No. T105340US02, filed concurrently herewith and entitled “PMOS Device with Multiple Rings for ESD Protection,” which is hereby incorporated by reference herein in its entirety.

### TECHNICAL FIELD

The present disclosure relates to the field of electronic circuits and systems, and more particularly, but not exclusively, to semiconductor devices implementing protection against electrostatic discharge (ESD) events.

### BACKGROUND

Electronic circuits and systems can be highly susceptible to ESD events of various types. For example, buffer circuits, line driver circuits and other types of circuits, which are illustratively utilized as part of input/output (I/O) circuitry in an integrated circuit, can be susceptible to ESD events occurring at one or more supply terminals and/or at one or more I/O terminals. These and other circuits in some applications are configured to provide an interface from one part of an integrated circuit to one or more other parts of the integrated circuit, to other integrated circuits and/or to other external components of an electronic system.

### SUMMARY

The present disclosure describes semiconductor devices, such as metal-oxide-semiconductor (MOS) field effect devices, as well as integrated circuits containing such semiconductor devices, and related methods. In some examples, a semiconductor device comprises an output circuit or other type of circuit that includes a field effect device and one or more associated rings as described herein. For example, such a semiconductor device is illustratively configured to provide enhanced ESD protection relative to conventional arrangements.

This summary is not an extensive overview of the disclosure. Rather, a purpose of the summary is to present some examples of the present disclosure in a simplified form as a prelude to a more detailed description that is presented later.

In some examples, a semiconductor device comprises a field effect transistor comprising a gate, a source region, and a drain region, the source and drain regions having a first conductivity type formed in a well region of a second conductivity type different than the first conductivity type, wherein the source and drain regions extend parallel to one another in a first direction. The semiconductor device further comprises a first metallization layer including first source and drain metal lines extending parallel to one another in the first direction and connected to the respective source and drain regions, and a second metallization layer including second source and drain metal lines connected to the respective first source and drain metal lines, with the second source and drain metal lines comprising a set of source metal lines that extend parallel to one another in the first direction, outward from an additional source metal line that extends in a second direction perpendicular to the first direction, and a set of drain metal lines that extend parallel to one another in the first direction, outward from an additional drain metal line that extends in the second direction perpendicular to the first direction.

In some other examples, an integrated circuit comprises an n-type field effect transistor of a circuit, the n-type field effect transistor including a gate coupled to a first node of the circuit, a source region coupled to a lower supply terminal of the circuit, and a drain region coupled to an output terminal of the circuit, and a p-type field effect transistor of the circuit, the p-type field effect transistor including a gate coupled to a second node of the circuit, a source region coupled to an upper supply terminal of the circuit, and a drain region coupled to the output terminal of the circuit, wherein the source and drain regions of the p-type field effect transistor extend parallel to one another in a first direction. The integrated circuit further comprises a first metallization layer including first source and drain metal lines extending parallel to one another in the first direction and connected to the respective source and drain regions of the p-type field effect transistor, and a second metallization layer including second source and drain metal lines connected to the respective first source and drain metal lines, with the second source and drain metal lines comprising a set of source metal lines that extend parallel to one another in the first direction, outward from an additional source metal line that extends in a second direction perpendicular to the first direction, and a set of drain metal lines that extend parallel to one another in the first direction, outward from an additional drain metal line that extends in the second direction perpendicular to the first direction.

In some additional examples, a method of manufacturing an integrated circuit comprises forming an n-type field effect transistor of a circuit, the n-type field effect transistor including a gate coupled to a first node of the circuit, a source region coupled to a lower supply terminal of the circuit, and a drain region coupled to an output terminal of the circuit, and forming a p-type field effect transistor of the circuit, the p-type field effect transistor including a gate coupled to a second node of the circuit, a source region coupled to an upper supply terminal of the circuit, and a drain region coupled to the output terminal of the circuit, wherein the source and drain regions of the p-type field effect transistor extend parallel to one another in a first direction. The method further comprises forming a first metallization layer including first source and drain metal lines extending parallel to one another in the first direction and connected to the respective source and drain regions of the p-type field effect transistor, and forming a second metallization layer including second source and drain metal lines connected to the respective first source and drain metal lines, with the second source and drain metal lines comprising a set of source metal lines that extend parallel to one another in the first direction, outward from an additional source metal line that extends in a second direction perpendicular to the first direction, and a set of drain metal lines that extend parallel to one another in the first direction, outward from an additional drain metal line that extends in the second direction perpendicular to the first direction.

### BRIEF DESCRIPTION OF THE DRAWINGS

FIG. 1 shows a schematic diagram of a semiconductor device in accordance with examples of the present disclosure;

FIG. 2 is a block diagram of an integrated circuit that includes a plurality of input circuits, a plurality of output circuits and additional circuitry in accordance with examples of the present disclosure;

FIG. 3 is a schematic circuit diagram of an implementation of the FIG. 1 semiconductor device in accordance with examples of the present disclosure;

FIGS. 4A and 4B illustrate respective different modes of operation of the FIG. 3 semiconductor device responsive to respective different ESD events in accordance with examples of the present disclosure;

FIG. 5A is a plan view of a semiconductor device comprising a p-type MOS (PMOS) device and associated rings in accordance with examples of the present disclosure;

FIG. 5B is a plan view showing additional details of example gate, source and drain layouts in the PMOS device of FIG. 5A;

FIGS. 6A and 6B are cross-sectional views illustrating respective different modes of operation of another semiconductor device in accordance with examples of the present disclosure;

FIGS. 7, 8 and 9 are plan views illustrating metallization layers in a semiconductor device in accordance with examples of the present disclosure;

FIG. 10 is a flow diagram illustrating a method of operating a semiconductor device comprising a PMOS device and associated rings in accordance with examples of the present disclosure; and

FIGS. 11 and 12 are flow diagrams illustrating respective methods of manufacturing an integrated circuit in accordance with examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein, such as transistors and other semiconductor-based circuitry, or portions and combinations thereof, can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

Integrated circuits or portions thereof may be damaged by an ESD event during manufacturing, assembly, testing and/or during normal operation in a given application. As described herein, an ESD event can be understood as including, for example, an event on an I/O or power pad or other externally accessible node of a circuit that creates an elevated voltage (e.g., with respect to VSS or other voltage reference node) that is higher than a voltage which is normally supplied to the pad (e.g., higher than VDD) or other ESD event that can stress or degrade a circuit component unless attenuated by ESD protection circuitry. For example, an ESD stress event may include events used in testing ESD immunity classification for the human body model (HBM Classes 0, 1A, 1B, 1C, 2, 3A and 3B), the charge device model (CDM Classes C1, C2, C3, C4, C5 and C6), and/or the machine model (MM Classes M1, M2, M3 and M4). The Human Body Model simulates ESD due to discharge from human beings, and the various levels of the HBM classifications are often used to describe an ESD stress event. CDM simulates the discharge of a charged device when it comes in contact with a conductive material, and MM represents a discharge from an object to the component. Many ICs include circuitry that can be damaged by ESD events that deliver high voltages to one or more IC terminals (e.g., pins, pads). These and other ESD events are intended to be encompassed by the term “ESD event” as broadly used herein.

In some examples, a semiconductor device comprises an output circuit or other type of circuit that includes a PMOS device or other field effect device and one or more associated rings as described herein. For example, such a semiconductor device is illustratively configured to provide enhanced ESD protection relative to conventional arrangements.

These and other examples provide technical solutions to significant problems of alternative approaches. For example, one or more such examples overcome significant challenges that can otherwise arise in implementing low-cost integrated circuits with limited area requirements. In some scenarios of this type, multiple instances of conventional ESD protection circuits typically cannot be included due to the cost and area restrictions. Moreover, some integrated circuits may have a significantly skewed form factor, with the integrated circuit being substantially longer in one lateral dimension than in the other, as well as particular edge terminal requirements, further complicating implementation of adequate levels of ESD protection. For example, a four-channel digital isolator integrated circuit may be about three times longer in one lateral dimension than the other lateral dimension, due to connection requirements for particular terminal types arranged along a particular edge of the integrated circuit. Such connection requirements can also prevent implementation of an ESD protective ground bus surrounding the integrated circuit. These and other factors can severely constrain the types of ESD protection that can be implemented, potentially leaving the integrated circuit vulnerable to ESD events.

Additional challenges arise with regard to the metallization layers utilized in implementing ESD protection in an integrated circuit. Typically, in an output circuit or other circuit comprising a PMOS device, it is desirable to increase the width of the source and drain metallization in order to provide additional current-carrying capacity during ESD events. However, increasing the width of the source and drain metallization increases the gate-to-source and gate-to-drain capacitances (e.g., due to metal lines overlapping gate electrodes), which can adversely impact the ability to meet strict integrated circuit performance requirements such as noise, operating speed and other functional specifications. These contradictory design goals present a significant challenge in configuring semiconductor devices to both provide ESD protection and meet performance requirements.

Semiconductor devices as described herein overcome these and other technical problems, by providing technical solutions in which a PMOS device is implemented with one or more associated rings as described herein. Such solutions provide enhanced ESD protection for semiconductor devices that are subject to significant cost, area and/or performance constraints, such as the above-noted digital isolator integrated circuits, as well as in numerous other integrated circuit applications. For example, integrated circuits that include output circuits implemented using PMOS devices with one or more associated rings as described herein can tolerate higher levels of ESD-induced stress during ESD events of various types, while also meeting other functional specifications of the particular integrated circuit application.

While various examples described herein may be expected to provide such or similar improvements, no particular result is a requirement of the present disclosure unless explicitly recited in a particular claim.

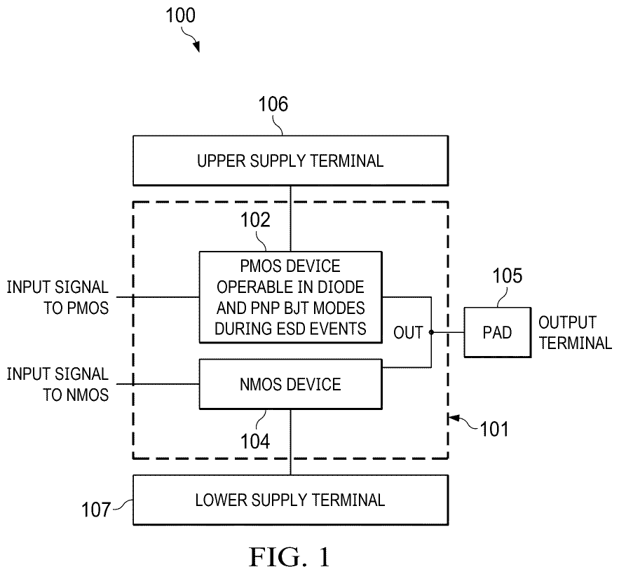

Referring now to FIG. 1, a semiconductor device 100 comprises a circuit 101 that includes a PMOS device 102 and an NMOS device 104 arranged as shown. The circuit 101 may be viewed as an illustrative example of what is also referred to herein as an “output circuit,” which may comprise a buffer circuit, a line driver circuit or another type of output circuit, although it is to be appreciated that many other types of circuits can be used in other examples. The term “circuit” as used herein is therefore intended to be broadly construed, and should not be viewed as being limited to output circuits or any other particular types of circuits.

The PMOS device 102 and the NMOS device 104 receive input signals at their respective inputs as shown. Although the input signals are illustratively distinct input signals as shown, in some examples, the same input signal is applied to the inputs of the PMOS device 102 and the NMOS device 104. Respective outputs of the PMOS device 102 and the NMOS device 104 drive a common circuit node, denoted OUT, that is coupled to a pad 105. The pad 105 illustratively represents an output terminal of the semiconductor device 100.

The circuit 101 is coupled between an upper supply terminal 106 and a lower supply terminal 107, illustratively corresponding to respective VDD and VSS supply terminals in some examples, although other types and arrangements of supply terminals can be used. Terms such as “upper supply terminal” and “lower supply terminal” as used herein are therefore intended to be broadly construed.

Also, the term “output terminal” as used herein is similarly intended to be broadly construed, and should not be viewed as being limited, for example, to a terminal corresponding to a common circuit node such as OUT and/or a pad such as pad 105 as shown in the example of FIG. 1. Numerous other types of output terminals can be used in other examples.

The circuit 101 in some examples comprises an output circuit that includes a complementary metal-oxide-semiconductor (CMOS) output buffer, illustratively arranged in a “push-pull” configuration, with the PMOS device 102 and the NMOS device 104 collectively providing a driver stage of the output buffer. Numerous other circuit arrangements are possible in other examples.

The PMOS device 102 in the present example is operable in different modes of operation responsive to respective ESD events of different types. These different modes illustratively include at least a diode mode of operation in response to an ESD event at the output terminal corresponding to pad 105, and a pnp bipolar junction transistor (BJT) mode of operation in response to an ESD event at the upper supply terminal 106. These modes of operation will be described in more detail below. Additional or alternative modes can be used in other examples.

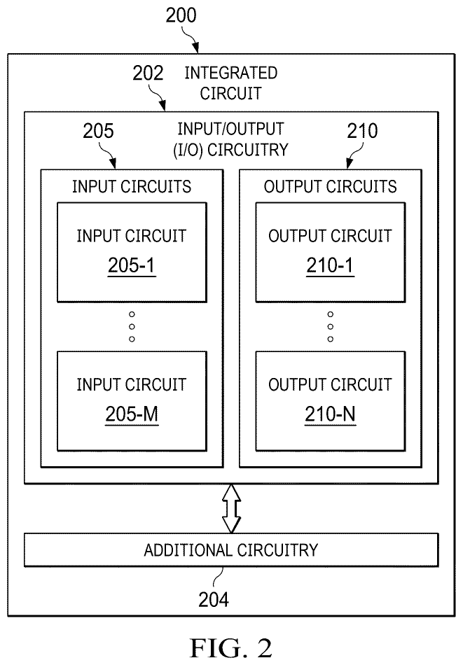

The semiconductor device 100 comprising circuit 101 is illustratively implemented as part of an integrated circuit, examples of which will now be described in more detail with reference to FIG. 2. In other examples, the semiconductor device 100 comprising circuit 101 can be implemented in other ways, such as at least partially in the form of discrete circuit components.

Referring now to FIG. 2, an example integrated circuit 200 is shown. The integrated circuit 200 comprises input/output (I/O) circuitry 202 coupled to additional circuitry 204. The I/O circuitry 202 comprises input circuits 205, including individual input circuits 205-1 through 205-M, and output circuits 210, including individual output circuits 210-1 through 210-N. In some examples, one or more of the output circuits 210 are each illustratively configured in the manner previously described in conjunction with FIG. 1. The variables M and N denote respective positive integers greater than one, which may vary depending upon the particular implementation, and in some examples can take on values such as 2, 10, 100, etc. Other types and arrangements of input and output circuits, including one or more input and/or output circuits configured in a manner different than that illustrated in FIG. 1, can be included in the integrated circuit 200. The additional circuitry 204 can comprise, for example, isolation circuitry, power management circuitry, serial communication processing circuitry, management bus processing circuitry and/or other core circuitry. A wide variety of other types and arrangements of circuitry can be implemented within the integrated circuit 200, in addition to the I/O circuitry 202 comprising input circuits 205 and output circuits 210.

In some examples, at least a subset of the input circuits 205 receive input signals from one or more external devices and/or or systems, not shown in FIG. 2, for further processing by the additional circuitry 204. Similarly, at least a subset of the output circuits 210 provide output signals from the additional circuitry 204 to one or more external devices and/or or systems, also not shown in FIG. 2. Numerous other integrated circuits can be configured to include one or more circuits of the type previously described in conjunction with FIG. 1.

As a more particular illustration, the integrated circuit 200 in some examples comprises an isolator circuit, such as a digital isolator circuit, with each of at least a subset of its output circuits 210 comprising an output circuit configured in the manner illustrated in FIG. 1. Again, numerous other types of integrated circuits can be used in other examples.

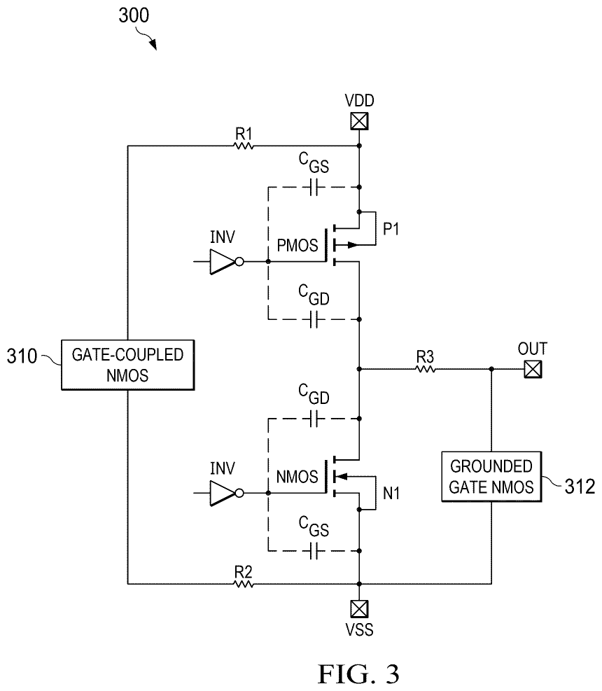

FIG. 3 shows an example semiconductor device 300 which illustrates one possible implementation of the semiconductor device 100 of FIG. 1. The semiconductor device 300 in this example includes an output circuit comprising a PMOS device P1 and an NMOS device N1, illustratively providing a driver stage of a CMOS output buffer in a push-pull configuration. Gate terminals of P1 and N1 are illustratively driven by outputs of respective instances of inverter INV, although in other examples a single inverter or other internal circuitry can drive the gate terminals of P1 and N1. P1 and N1 are coupled between an upper supply terminal, illustratively VDD, and a lower supply terminal, illustratively VSS, as shown. More particularly, a source terminal of P1 is coupled to VDD, and a source terminal of N1 is coupled to VSS. Drain terminals of P1 and N1 are coupled together at a common output node of the output circuit. The common output node is coupled via resistor R3 to an output terminal OUT of the output circuit. The gate-to-source capacitances of P1 and N1 are denoted as C_{GS}, and gate-to-drain capacitances of P1 and N1 are denoted as C_{GD}. Resistor R3 in some examples is implemented as a polysilicon resistor, such as a high sheet resistance (HSR) polysilicon resistor, and has a value of about 25 ohms, although other resistor types and values can be used in other examples.

The semiconductor device 300 additionally comprises a gate-coupled NMOS (GCNMOS) device 310 (e.g., an NMOS device with its gate connected to its drain) coupled via respective resistors R1 and R2 between VDD and VSS. The resistors R1 and R2 in some examples are implemented as respective metal routing resistors, in one or more metallization layers of the semiconductor device 300, and have a combined resistance R1+R2 that is less than or equal to about 2 ohms, although again other resistor types and values can be used. The semiconductor device 300 further comprises a grounded-gate NMOS (GGNMOS) device 312 coupled between the output terminal OUT and VSS. The GCNMOS device 310 and GGNMOS device 312 are examples of ESD protection circuits that are included in a semiconductor device in some examples. However, the GCNMOS device 310 and/or the GGNMOS device 312 can be eliminated in other examples. Alternatively, one or more additional GCNMOS devices and/or one or more additional GGNMOS devices may be included in the semiconductor device 300.

As indicated above, examples described herein advantageously provide enhanced ESD protection for output circuits such as that illustrated in FIG. 3, including in applications including low-cost integrated circuits with limited area requirements and/or other restrictions such as skewed form factors. In many such applications, for example, it may not be possible to increase the number of GCNMOS devices and/or the number of GGNMOS devices to increase the level of ESD protection. Similarly, it may not be possible to provide increased ESD protection by implementing a ground bus surrounding the integrated circuit, due to the previously-mentioned edge terminal requirements. In the output circuit of FIG. 3, these and other challenges are advantageously overcome, and enhanced ESD protection is provided, at least in part by implementing the PMOS device P1 of the output circuit in association with one or more rings that are configured to provide enhanced ESD protection in diode and pnp BJT modes of operation, responsive to different ESD events of different types.

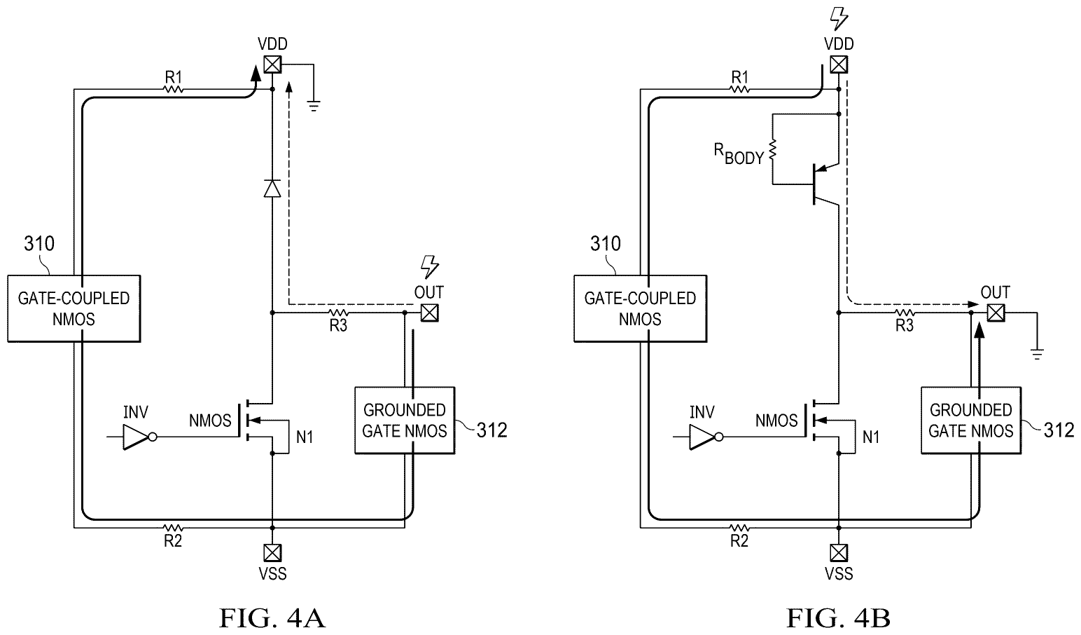

FIGS. 4A and 4B illustrate the respective diode and pnp BJT modes of operation of the PMOS device P1 of the semiconductor device 300 responsive to respective different ESD events of different types in accordance with examples of the present disclosure.

Referring to FIG. 4A, the diode mode of operation of the PMOS device P1 is illustratively triggered responsive to an ESD event at the output terminal OUT. In this mode, the PMOS device P1 operates as at least one diode configured to carry ESD-induced current from the output terminal OUT to the upper supply terminal VDD, as illustrated by the dashed arrow in FIG. 4A. Additional ESD-induced current is carried from the output terminal OUT to the upper supply terminal VDD via the GCNMOS and GGNMOS devices, as illustrated by the solid arrow in FIG. 4A.

Referring to FIG. 4B, the pnp BJT mode of operation of the PMOS device P1 is illustratively triggered responsive to an ESD event at the upper supply terminal VDD. In this mode, the PMOS device P1 operates as a pnp BJT configured to carry ESD-induced current from the upper supply terminal VDD to the output terminal OUT, as illustrated by the dashed arrow in FIG. 4B. A body resistance R_{BODY}, illustratively a body resistance of an n-type well region in which the source and drain regions of P1 are formed in some examples described herein, is shown as being coupled between an emitter and a base of the pnp BJT. Additional ESD-induced current is carried from the upper supply terminal VDD to the output terminal OUT via the GCNMOS and GGNMOS devices, as illustrated by the solid arrow in FIG. 4B.

In some examples described herein, the PMOS device P1 is configured with one or more rings that serve to facilitate the resolution of what would otherwise be conflicting requirements of the above-described diode and pnp BJT modes of operation, advantageously resulting in improved ESD performance in both modes. For example, absent use of techniques disclosed herein, increasing the current-carrying capacity of the PMOS device P1 in the diode mode of operation might otherwise decrease the current-carrying capacity of the PMOS device P1 in the pnp BJT mode, and vice versa. Some examples disclosed herein provide improved current-carrying capacity in both the diode mode and the pnp BJT mode, through the use of one or rings implemented in association with the PMOS device P1.

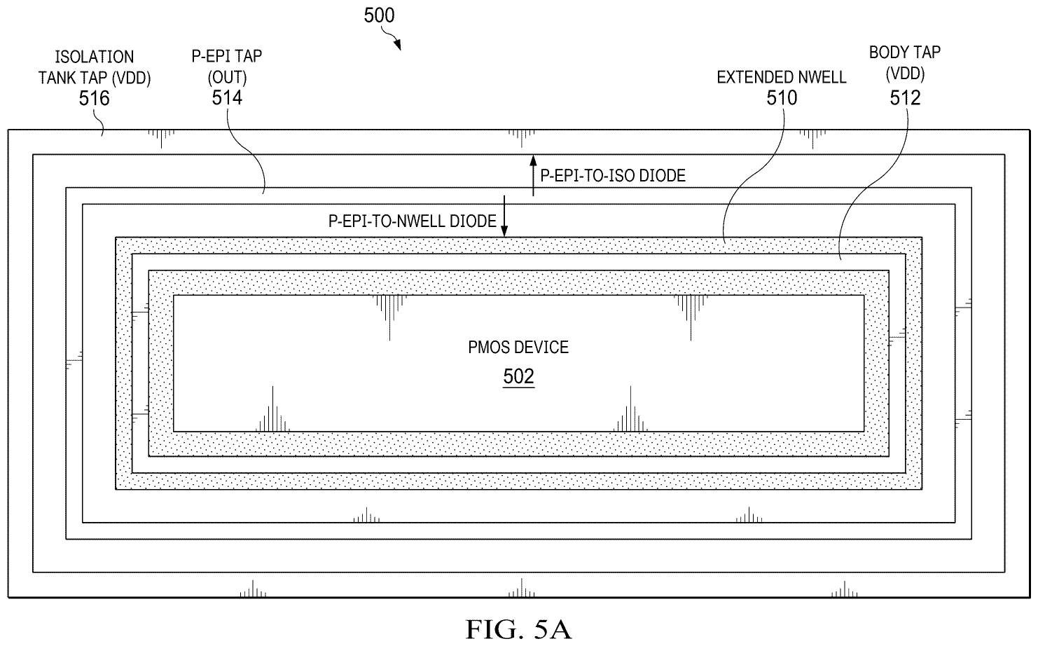

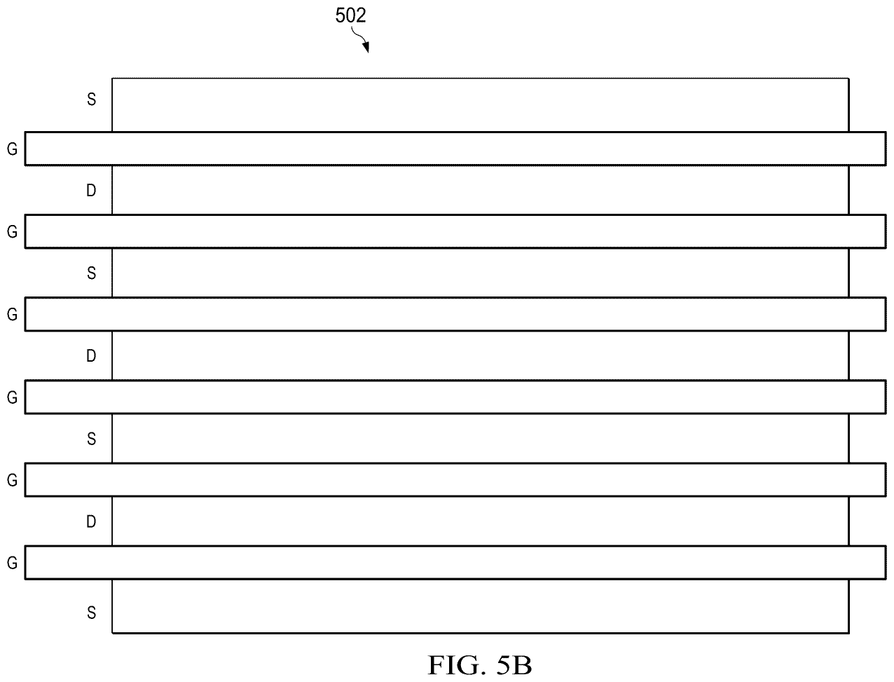

FIG. 5A shows a plan view of a semiconductor device 500 in accordance with examples of the present disclosure. The semiconductor device 500 illustrates one possible implementation of a portion of the semiconductor device 300 of FIG. 3. The semiconductor device 500 comprises a PMOS device 502 that may be an example of or include aspects of the PMOS device P1 described with reference to FIGS. 3, 4A, and 4B. The PMOS device 502 is formed in an n-type well (NWELL) region 510, also referred to in this example as an “extended” NWELL region, as the NWELL region is illustratively extended (e.g., laterally extended beyond source (S) and drain (D) regions) to provide increased body resistance (e.g., R_{BODY} depicted in FIG. 4B). A body tap 512 corresponds to a first ring that is formed in the NWELL region 510 and laterally surrounds the PMOS device 502. The body tap 512 corresponding to the first ring is coupled to the upper supply terminal VDD. A p-type epitaxial (“p-epi”) tap 514 corresponds to a second ring that is formed in a p-epi region and laterally surrounds the first ring. The p-epi tap 514 corresponding to the second ring is coupled to the output terminal OUT. An isolation (“iso”) tank tap 516 corresponds to a third ring that is connected to an n-type buried layer and laterally surrounds the second ring. The iso tank tap 516 corresponding to the third ring is also coupled to the upper supply terminal VDD. It should be noted in this regard that taps 512, 514 and 516 in this example may be viewed as illustrations of at least portions of what are more generally referred to herein as respective “rings.”

The term “ring” as used herein is therefore intended to be broadly construed, and illustratively includes at least one corresponding semiconductor region, and may include additional structure, such as, for example, metal lines in one or more metallization layers, where such metal lines couple the at least one semiconductor region of a given one of the rings to a particular terminal, such as the upper supply terminal VDD in the case of the first and third rings of FIG. 5A, or the output terminal OUT in the case of the second ring of FIG. 5A. Numerous other types and arrangements of rings can be used in other examples. Accordingly, other examples can include only a single ring, only two rings, or more than three rings. Also, a “ring” as the term is broadly construed herein may have one or more breaks in its perimeter. In other words, the ring need not be fully continuous around the entirety of its perimeter, and in some examples may instead be substantially continuous, with one or more breaks in its perimeter, but nonetheless laterally surrounding semiconductor structures that are encompassed within that perimeter. Terms such as “laterally surrounds” and “laterally surrounding” as used herein are therefore also intended to be broadly construed.

The first, second and third rings of the FIG. 5A example are generally configured to provide enhanced ESD protection in the semiconductor device 500. For example, a first diode is formed at least in part between the p-epi tap 514 and the NWELL region 510, as denoted generally by the downward arrow in FIG. 5A, and may be referred to as a p-epi-to-NWELL diode. A second diode is formed at least in part between the p-epi tap 514 and the iso tank tap 516, as denoted generally by the upward arrow in FIG. 5A, and may be referred to as a p-epi-to-iso diode. Both of these diodes are operative in the diode mode of operation of FIG. 4A, to carry current from the output terminal OUT to the upper supply terminal VDD in response to an ESD event at the output terminal OUT. These first and second diodes are illustratively implemented as strong perimeter diodes, providing substantially improved current-carrying capacity in the diode mode of operation during the ESD event at the output terminal OUT.

In some examples, the p-epi tap 514 forming the second ring is illustratively implemented at a minimum design rule spacing relative to the NWELL region 510 that includes the body tap 512 forming the first ring, to provide the first diode, also referred to as the p-epi-to-NWELL diode, in accordance with design rules of a process used to produce the semiconductor device 500. Additionally or alternatively, the p-epi tap 514 forming the second ring is illustratively implemented at a minimum design rule spacing relative to the iso tank tap 516 forming the third ring, to provide the second diode, also referred to as the p-epi-to-iso diode. Moreover, implementing the NWELL region 510 that includes the body tap 512 forming the first ring at the minimum design rule spacing relative to the p-epi tap 514 allows the body tap 512 to be placed close to a peripheral edge of the NWELL region 510, which increases the body resistance (e.g., R_{BODY} depicted in FIG. 4B) of the NWELL region 510, resulting in improved current-carrying capacity in the pnp BJT mode of operation during the ESD event at the upper supply terminal VDD. Accordingly, illustrative examples provide improved ESD performance in both diode and pnp BJT modes, by efficiently and effectively resolving their otherwise conflicting requirements. Other spacings can be used in other examples, and the above-noted minimum design rule spacings are examples only. These and other minimum design rule spacings or other design rule parameters referred to herein will generally vary depending on factors such as the particular process utilized to form the semiconductor device. Also, the term “tap” as used herein is intended to be broadly construed, and may comprise a ring or a portion of a ring. A ring in some examples can therefore include at least a tap and possibly one or more other related structures.

FIG. 5B is a plan view showing additional details of example gate, source and drain layouts in the PMOS device 502 of FIG. 5A. The gate (G), source (S) and drain (D) regions are arranged in parallel “fingers” as illustrated. The gate may be implemented using any appropriate conductive material, such as polysilicon (e.g., doped polysilicon), metal (e.g., tungsten (W), aluminum (Al), titanium (Ti), tantalum (Ta) or the like), as well as combinations of these and/or other materials. In some examples, the PMOS device 502 includes about eight fingers, each approximately 50 micrometers (μm) wide, with channel lengths of about 0.25 μm to 1.00 μm, although more or fewer fingers and alternative width/length values can be used in other examples.

Advantageously, the example ring arrangement of FIG. 5A avoids the need for numerous interspersed NWELL taps between the fingers in the FIG. 5B layout, as such NWELL taps are instead “pushed out” and implemented as the first ring corresponding to body tap 512 in FIG. 5A, while also providing significantly enhanced ESD protection relative to alternative arrangements.

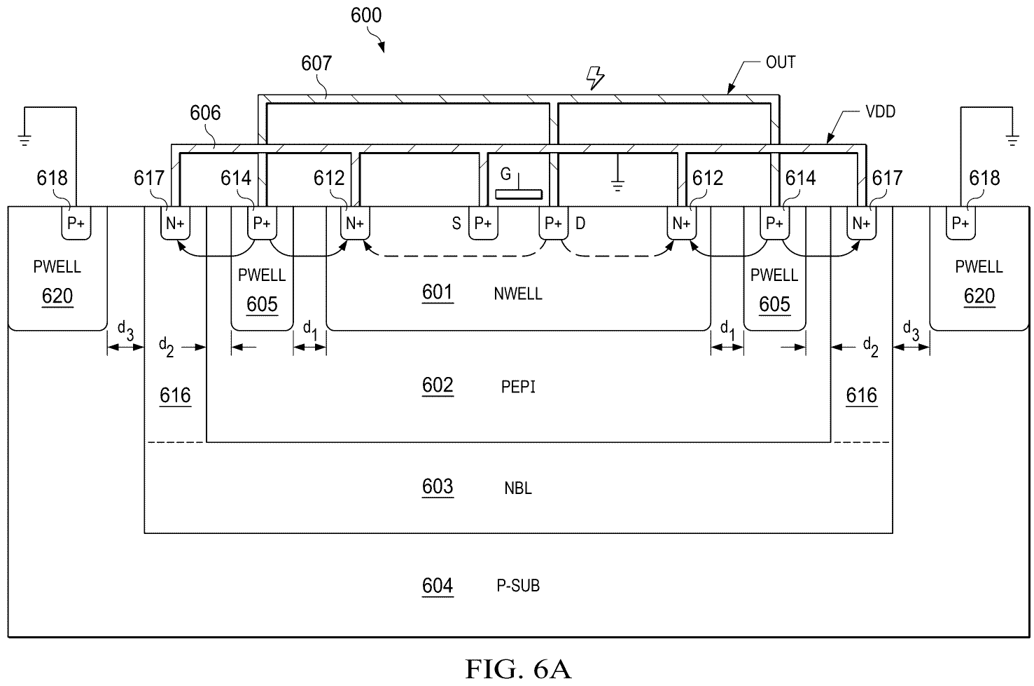

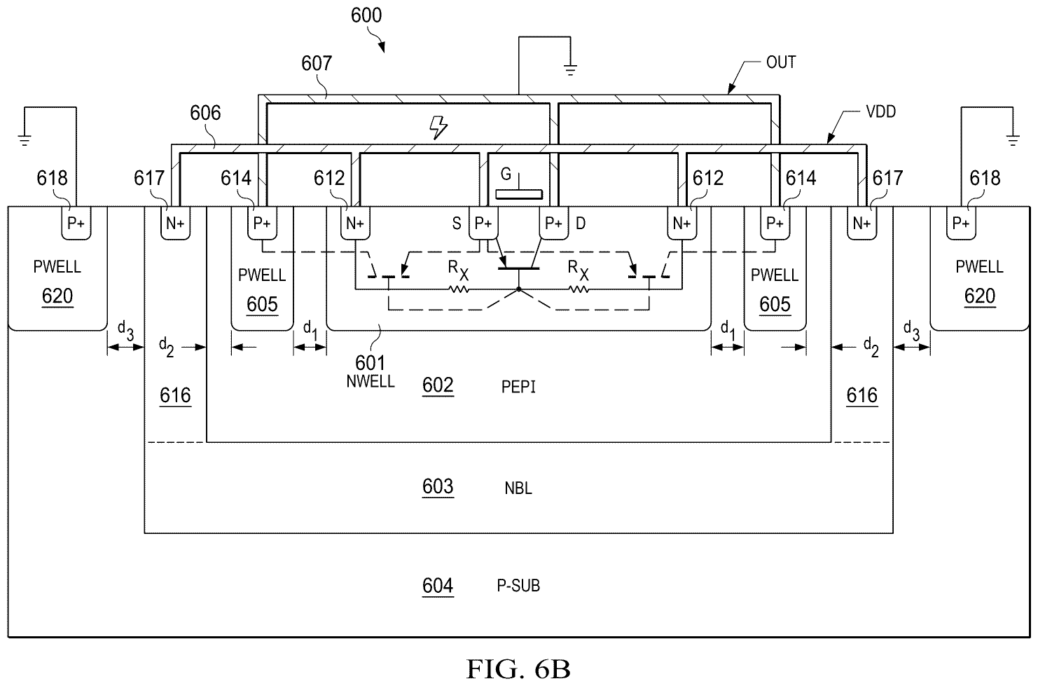

Additional details of the above-described first, second and third rings and the operation of the corresponding PMOS device in diode and pnp BJT modes will now be described with reference to respective FIGS. 6A and 6B.

FIGS. 6A and 6B show cross-sectional views of a semiconductor device 600, illustrating aspects of its operation in respective diode and pnp BJT modes. The semiconductor device 600 may be an example of or include aspects of the PMOS device P1 described with reference to FIGS. 3, 4A, and 4B and/or the PMOS device 502 described with reference to FIGS. 5A and 5B. Referring initially to FIG. 6A, which illustratively corresponds to the diode mode of operation, the semiconductor device 600 comprises a PMOS device with source and drain regions denoted S and D, and a gate denoted G. The semiconductor device 600 further comprises first, second and third rings, similar to those previously described in conjunction with the example of FIG. 5A. The source region of the PMOS device is coupled to the upper supply terminal VDD of a circuit, illustratively an output circuit of the type shown in FIG. 3, that includes the PMOS device, and the drain region of the PMOS device is coupled to the output terminal OUT of the circuit.

In this example, the source region is a first p-type region formed in an n-type well region 601, illustratively an NWELL region (e.g., NWELL region 510), and the drain region is a second p-type region formed in the n-type well region 601. The n-type well region 601 is formed in a p-type epitaxial region 602 over a p-type substrate 604, denoted in the figure as PEPI and P-SUB, respectively. Terminals 606 and 607 correspond to upper supply terminal VDD and output terminal OUT, respectively.

An n-type region 612 formed in the n-type well region 601 forms a first ring (e.g., the body tap 512) that laterally surrounds the first and second p-type regions providing the respective source and drain regions. The n-type region 612 is connected to the upper supply terminal VDD.

A p-type well region (PWELL) 605 is formed in the p-type epitaxial region 602, and a p+ region 614 is formed in the p-type well region 605. The p+ region 614 includes a greater dopant concentration than the p-type well region 605—e.g., to provide a low resistance path for electrical connection to the p-type well region 605. The p-type well region 605 and the p+ region 614 may collectively form a p-epi tap (e.g., the p-epi tap 514) that forms a second ring that laterally surrounds the n-type well region 601. The p-type well region 605 is connected to the output terminal OUT through the p+ region 614 formed in the p-type well region 605. In this example, the p-type well region 605 and the p+ region 614 may be collectively referred to as a third p-type region.

The n-type region 612 forming the first ring is illustratively arranged closer to a periphery of the n-type well region 601 than to respective peripheries of the first and second p-type regions providing the respective source and drain regions. Such an arrangement advantageously serves to increase the above-noted body resistance, thereby providing improved ESD protection in the pnp BJT mode, as will be described below in conjunction with FIG. 6B.

In some examples, a lateral distance between the n-type well region 601 and the p-type well region 605 corresponds to a minimum design rule spacing d₁ between these regions, as shown in FIGS. 6A and 6B. In some examples, the minimum design rule spacing d₁ is less than about 1.0 μm, although other spacings may be used in other examples.

The semiconductor device 600 in the present example further comprises an n-type buried layer (NBL) 603 disposed between the p-type epitaxial region 602 and the p-type substrate 604, and an n-type isolation region 616 extended from a surface of the p-type epitaxial region 602 to the n-type buried layer 603. The n-type isolation region 616 forms a third ring that laterally surrounds the second ring (e.g., the p-type well region 605 and the p+ region 614), and is connected to the upper supply terminal VDD through an n-type region 617 (depicted as an n+ region in the n-type isolation region 616 in FIGS. 6A and 6B) formed in the n-type isolation region 616. The n-type region 617 (e.g., the n+ region in the n-type isolation region 616) includes a greater dopant concentration than the n-type isolation region 616—e.g., to provide a low resistance path for electrical connection to the n-type isolation region 616. The n-type buried layer 603 and the n-type isolation region 616 collectively form an isolation tank that includes the PMOS device.

In some examples, a lateral distance between the p-type well region 605 and the n-type isolation region 616 corresponds to a minimum design rule spacing d₂ between these regions. The minimum design rule spacing d₂ in some examples is about 7.0 μm, although other spacings could be used.

The semiconductor device 600 in this example also includes substrate ground connections provided via an additional p-type region 618 formed in an additional p-type well region 620.

In some examples, a lateral distance between the n-type isolation region 616 and the additional p-well region 620 corresponds to a minimum design rule spacing d₃ between these regions. The minimum design rule spacing d₃ in some examples is about 2.0 μm, although again other spacings could be used. Additional or alternative regions may also be subject to minimum design rule spacings in other examples, and the particular minimum design rule spacings d₁, d₂ and d₃ described above are presented by way of illustration only.

In some examples, the source and drain regions and the other p+ regions illustratively have dopant concentrations in the range from about 1×10²⁰ cm⁻³ to about 2×10²⁰ cm⁻³, using p-type dopants such as boron. The n+ regions illustratively have a similar range of dopant concentrations, but using n-type dopants such as phosphorous. The n-type well region 601, the p-type well region 605 and the p-type well region 620 may each have dopant concentrations of approximately 6×10¹⁷ cm⁻³. The p-type epitaxial region 602 illustratively has a dopant concentration in the range from about 2×10¹⁵ cm⁻³ to about 3×10¹⁵ cm⁻³. The n-type buried layer 603 illustratively has a dopant concentration in the range from about 5×10¹⁸ cm⁻³ to about 1×10¹⁹ cm⁻³. The p-type substrate 604 illustratively has a dopant concentration of approximately 2×10¹⁵ cm⁻³. It is to be appreciated, however, that the foregoing dopant concentrations and associated dopants are examples only, and can be varied in accordance with the particular needs of a given implementation.

As is apparent from the above description, the semiconductor device 600 of FIGS. 6A and 6B comprises first, second and third rings, with the first ring being encompassed within a periphery of the second ring, and the second ring being encompassed within a periphery of the third ring. Again, numerous other arrangements of one or more rings may be used in other examples.

Although not shown in FIGS. 6A and 6B, an n-type field effect device may be included in the semiconductor device 600 in some examples. The n-type field effect device illustratively comprises an NMOS device such as the NMOS device N1 previously described in conjunction with FIG. 3, which together with the PMOS device forms at least a portion of a driver stage of an output circuit. The NMOS device illustratively comprises source and drain regions and a gate, with the gate being coupled to an internal node of the output circuit, the source region being coupled to the lower supply terminal VSS of the output circuit and the drain region being coupled to the output terminal OUT of the output circuit, as previously described in conjunction with FIG. 3.

As indicated previously, the PMOS device in the semiconductor device 600 is operable in different modes of operation responsive to respective ESD events of different types. The different modes of operation comprise at least a diode mode of operation in response to an ESD event at the output terminal OUT, as illustrated in FIG. 6A, and a pnp BJT mode of operation in response to an ESD event at the upper supply terminal VDD, as illustrated in FIG. 6B.

Referring to FIG. 6A, in the diode mode of operation, the second ring including the p-type well region 605 and the p+ region 614 operates as an anode of a first diode and the first ring formed by the n-type region 612 in conjunction with the n-type well region 601 operates as a cathode of the first diode to carry current from the output terminal OUT to the upper supply terminal VDD during an ESD event at the output terminal OUT, as illustrated by a solid arrow between the p+ region 614 and the n-type region 612 in the figure. Also in the diode mode of operation, the second ring operates as an anode of a second diode, and the n-type isolation region 616 operates as a cathode of the second diode, to carry additional current from the output terminal OUT to the upper supply terminal VDD during the ESD event at the output terminal OUT, as illustrated by a solid arrow between the p+ region 614 and the n-type region 617 in the n-type isolation region 616 in the figure. As noted above, the n-type isolation region 616 forms the third ring that laterally surrounds the p-type well region 605 and the p+ region 614, and is connected to the upper supply terminal VDD. Additional current is carried in this mode between the second p-type region providing the drain region of the PMOS device, and the n-type region 612, through the n-type well region 601, as illustrated by the dashed arrows in the figure. The solid arrows generally indicate examples of primary or relatively “major” current paths during the ESD event at the output terminal OUT, and the dashed arrows generally indicate examples of secondary or relatively “minor” current paths during the ESD event at the output terminal OUT.

The above-noted first and second diodes provide substantially improved current-carrying capacity in the diode mode of operation during the ESD event at the output terminal OUT. In some examples, the first and second diodes comprise the respective p-epi-to-NWELL and p-epi-to-iso diodes described previously, with the p-type well region 605 of the second ring being implemented at a minimum design rule spacing relative to the n-type well region 601 containing the n-type region 612 of the first ring, to provide the first diode, also referred to as the p-epi-to-NWELL diode. Additionally or alternatively, the p-type well region 605 of the second ring is illustratively implemented at a minimum design rule spacing relative to the n-type isolation region 616 of the third ring, to provide the second diode, also referred to as the p-epi-to-iso diode. Again, other spacings can be used in other examples.

Referring to FIG. 6B, in the pnp BJT mode of operation, the first p-type region providing the source region of the PMOS device operates as an emitter of a pnp BJT, the n-type well region 601 operates as a base of the pnp BJT, and the second p-type region providing the drain region of the PMOS device operates as a collector of the pnp BJT, to carry current from the upper supply terminal VDD to the output terminal OUT during an ESD event at the upper supply terminal VDD. The body resistance of the n-type well region is illustrated in this figure as a pair of resistors, each denoted R_{X}, arranged between the base of the pnp BJT and the first ring formed by n-type region 612. Additional current is carried in this mode between the first p-type region providing the source region and the second ring including the p-type well region 605 and the p+ region 614, via two additional pnp BJTs shown in dashed outline in the figure. The solid lines associated with pnp BJT terminals generally indicate examples of primary or relatively “major” current paths during the ESD event at the upper supply terminal VDD, and the dashed lines associated with pnp BJT terminals generally indicate examples of secondary or relatively “minor” current paths during the ESD event at the upper supply terminal VDD.

In the examples of FIGS. 6A and 6B, the above-noted first and second diodes provide substantial additional current-carrying capacity in the diode mode, allowing the n-type region 612 of the first ring to be placed close to a peripheral edge of the n-type well region 601, thereby increasing the body resistance and providing substantial additional current-carrying capacity in the pnp BJT mode—e.g., such an arrangement is more efficient in activating (triggering) the pnp BJT mode. As indicated above, these and other examples advantageously facilitate the resolution of what would otherwise be conflicting requirements of the diode and pnp BJT modes of operation, resulting in improved ESD performance in both modes.

The examples shown in FIGS. 6A and 6B allow the PMOS device to be implemented in a highly area-efficient manner, with substantial current-carrying capacity in both diode and pnp BJT modes of operation, while also meeting other required functional specifications.

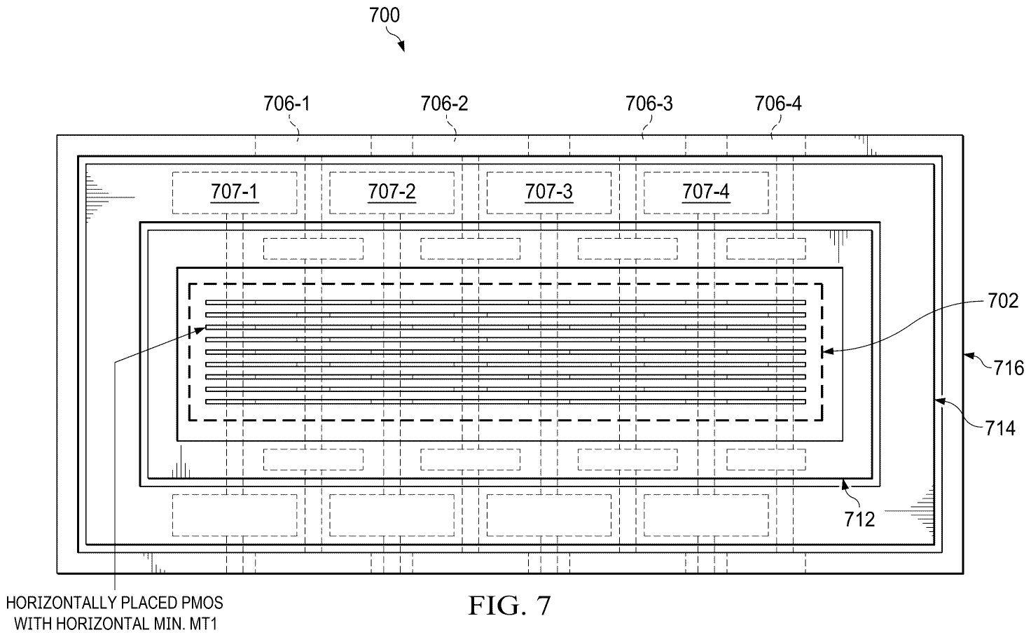

Additional aspects of some examples will now be described with reference to FIGS. 7 through 9. These aspects generally relate to metallization layers utilized in implementing a PMOS device with one or more rings as described above, for improved performance in the presence of ESD events of various types.

As mentioned previously, additional challenges arise with regard to the metallization layers utilized in implementing ESD protection in an integrated circuit. The examples to be described in conjunction with FIGS. 7 through 9 overcome these challenges, providing an output circuit or other circuit comprising a PMOS device in which gate-to-source and gate-to-drain capacitances can be significantly reduced, while still providing substantial current-carrying capacity during ESD events, and meeting strict integrated circuit performance requirements such as noise, operating speed and other functional specifications.

In some examples, there are only a limited number of metallization layers available, which can place additional restrictions on the configuration of the source and drain metallization. For example, in a digital isolator integrated circuit of the type mentioned elsewhere herein, there may be only three metallization layers available due to cost restrictions, with the highest metallization layer being utilized for routing to pads, leaving only the first two metallization layers to support ESD current-carrying capacity for the source and drain metallization.

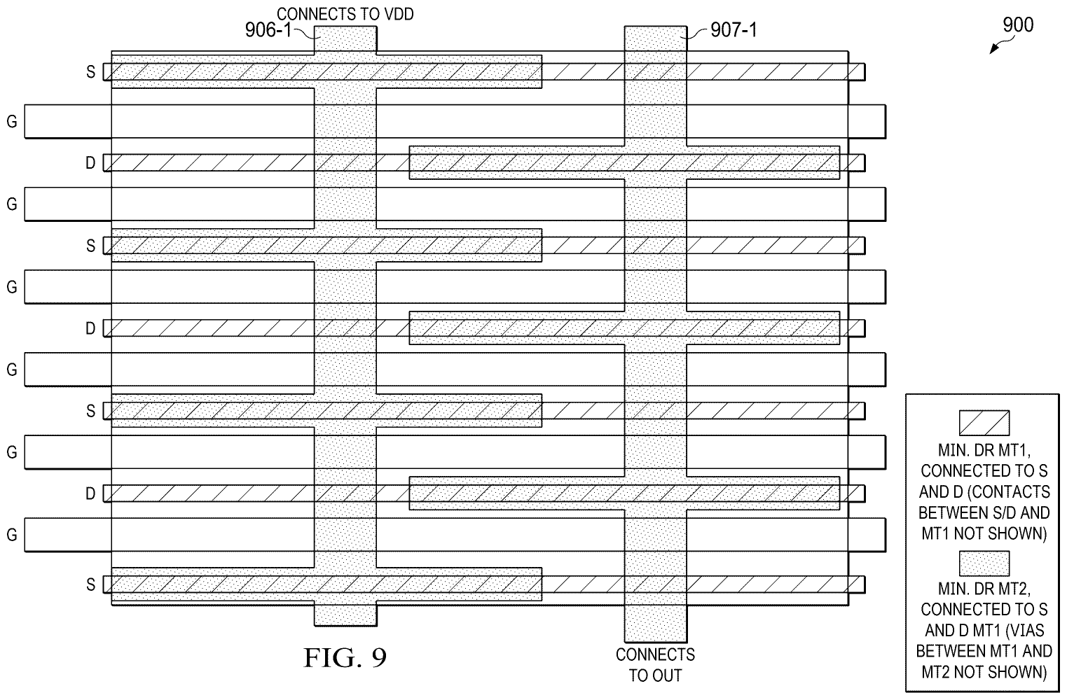

As was previously described in conjunction with FIGS. 5A and 5B, the PMOS device 502 is arranged with the source and drain regions parallel to a long dimension of the PMOS device 502. A similar arrangement is utilized in the examples of FIGS. 7 and 9. Such an arrangement of source and drain regions facilitates the implementation of the improved source and drain metallization layers to be described below.

Referring now to FIG. 7, a semiconductor device 700 comprises a PMOS device 702 arranged with its source and drain fingers parallel to a long dimension of the PMOS device 702. The semiconductor device 700 may be an example of or include aspects of the semiconductor device 600 described with reference to FIGS. 6A and 6B. The PMOS device 702 may be an example of or include aspects of the PMOS device P1 described with reference to FIGS. 3, 4A, and 4B and/or the PMOS device 502 described with reference to FIGS. 5A and 5B. The semiconductor device 700 further comprises a first ring 712 laterally surrounding the PMOS device 702, a second ring 714 laterally surrounding the first ring 712, and a third ring 716 laterally surrounding the second ring 714. The first, second and third rings 712, 714 and 716 in some examples correspond generally to the respective first, second and third rings provided by the body tap 512, the p-epi tap 514 and the iso tank tap 516 in the example of FIG. 5.

The PMOS device 702 illustratively comprises a gate, a source region, and a drain region, with the source and drain regions having a first conductivity type, illustratively p-type conductivity in the present example, and being formed in a well region of a second conductivity type, illustratively n-type conductivity in the present example, although other types and arrangements of semiconductor devices, regions and conductivity types can be used in other examples. As indicated above, the source and drain regions extend parallel to one another in a first direction, illustratively the long dimension of the PMOS device 702.

The semiconductor device 700 further comprises a first metallization layer including first source and drain metal lines extending parallel to one another in the first direction and connected to the respective source and drain regions. The first metallization layer is also referred to herein as a MT1 layer. As indicated by the arrow in FIG. 7, the PMOS device 702 is horizontally placed as described above, and utilizes horizontal MT1 lines with minimum width for its source and drain metallization in the first metallization layer. In some examples, the minimum width is a minimum design rule width, and may be about 0.3 μm to 0.5 μm, although other values could be used, and will generally vary depending on factors such as the particular process used to form the semiconductor device 700.

The semiconductor device 700 further comprises a second metallization layer including second source and drain metal lines connected to the respective first source and drain metal lines of the first metallization layer. The second metallization layer is also referred to herein as an MT2 layer. The second source and drain metal lines comprise a set of source metal lines that extend parallel to one another in the first direction, outward from an additional source metal line that extends in a second direction perpendicular to the first direction, and a set of drain metal lines that extend parallel to one another in the first direction, outward from an additional drain metal line that extends in the second direction perpendicular to the first direction.

As shown in FIG. 7, the source regions are coupled to the first and third rings 712 and 716 via the first and second source metal lines of the first and second metallization layers, as generally illustrated by source metallization portions 706-1, 706-2, 706-3 and 706-4. The source metal lines are also coupled to the upper supply terminal VDD, although that connection is not explicitly shown in the figure.

The drain regions are coupled to the second ring 714 via the first and second drain metal lines of the first and second metallization layers, as generally illustrated by drain metallization portions 707-1, 707-2, 707-3 and 707-4. The drain metal lines are also coupled to the output terminal OUT, although that connection is not explicitly shown in the figure.

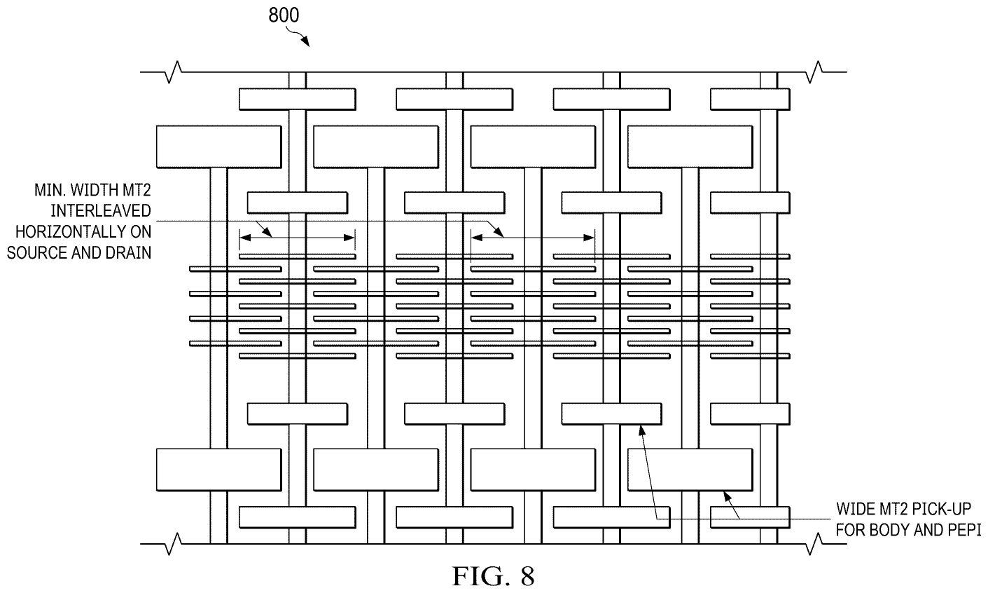

FIG. 8 shows a second metallization layer 800 of the semiconductor device 700 in isolation from the first metallization layer. As indicated by the arrows in the figure, the second source and drain metal lines of the second metallization layer in this example include minimum width MT2 lines, interleaved horizontally on the source and drain as shown, with wider vertical MT2 lines utilized to provide connections or “pick-ups” to the first ring, illustratively corresponding to a body tap, and the second ring, illustratively corresponding to a p-epi tap. The wider vertical MT2 lines of the second metallization layer 800 are similarly utilized to provide connections to the third ring, illustratively corresponding to an iso tank tap. In some examples, the minimum width MT2 lines may be about 0.3 μm to 0.5 μm wide, and the wider vertical MT2 lines may be about 2.0 μm to 7.0 μm wide, although other values could be used. These values in some examples correspond to minimum design rule widths for the process used to form the semiconductor device 700.

Referring now to FIG. 9, another example of the above-described arrangement of first and second metallization layers is shown. In this example, a semiconductor device 900 comprises source and drain regions S and D, arranged in parallel as shown, and corresponding gate G. The semiconductor device 900 may be an example of or include aspects of the semiconductor device 700 described with reference to FIGS. 7 and 8. The gate is illustratively implemented as a polysilicon gate, although as indicated previously, other gate materials can be used in other examples. First and second metallization layers MT1 and MT2 are shown in this example using respective different shadings, in accordance with the figure legend. First source and drain metal lines of the first metallization layer MT1 are connected to the respective source and drain regions, and may have a minimum design rule width, in accordance with design rules of a process used to produce the semiconductor device 900. Contacts between the source and drain regions and the first metallization layer MT1 are not explicitly shown in this figure, for clarity and simplicity of illustration. Also, second source and drain metal lines of the second metallization layer MT2 are connected to the respective first source and drain metal lines of the first metallization layer MT1, illustratively using vias, although such vias are not explicitly shown in the figure, again for clarity and simplicity of illustration.

In this example, the second metallization layer MT2 includes a source metallization portion 906-1 that connects to an upper supply terminal VDD of a circuit that includes the semiconductor device 900, and a drain metallization portion 907-1 that connects to an output terminal OUT of the circuit that includes the semiconductor device 900. In some examples, the source metallization portion 906-1 also connects to first and third rings of the type described previously, such as first and third rings 712 and 716 in the example of FIG. 7, and the drain metallization portion 907-1 also connects to a second ring of the type described previously, such as the second ring 714 in the example of FIG. 7, although numerous other arrangements of one or more rings and associated connections can be used in other examples.

The source metallization portion 906-1 of the second metallization layer MT2 more particular comprises a set of source metal lines that extend parallel to one another in a first direction, illustratively a horizontal direction in the plane of the figure, and outward from an additional source metal line that extends in a second direction perpendicular to the first direction, illustratively a vertical direction in the plane of the figure.

Similarly, the drain metallization portion 907-1 of the second metallization layer MT2 more particular comprises a set of drain metal lines that extend parallel to one another in the first direction, and outward from an additional drain metal line that extends in the second direction perpendicular to the first direction.

In the present example, the first source and drain metal lines of the first metallization layer MT1 do not overlap with the gate G of the semiconductor device 900. Additionally or alternatively, at least a subset of the first source and drain metal lines each may have a minimum design rule width, where “design rule” is also denoted as DR in the figure legend.

Also in the present example, the second source metal lines of the second metallization layer MT2, other than the additional source metal line extending in the second direction perpendicular to the first direction, do not overlap with the gate G of the semiconductor device 900. Additionally or alternatively, at least a subset of the second source metal lines of the second metallization layer MT2, other than the additional source metal line, each may have a minimum design rule width.

Similarly, in the present example, the second drain metal lines of the second metallization layer MT2, other than the additional drain metal line extending in the second direction perpendicular to the first direction, do not overlap with the gate G of the semiconductor device 900. Additionally or alternatively, at least a subset of the second drain metal lines of the second metallization layer MT2, other than the additional drain metal line, each may have a minimum design rule width.

As illustrated in the figure, the set of source metal lines of the source metallization portion 906-1 of the second metallization layer MT2 that extend parallel to one another in the first direction each have a first width, and the additional source metal line that extends in the second direction perpendicular to the first direction has a second width that is greater than the first width. The particular relative widths shown in the figure for the set of source metal lines and the additional source metal line of the source metallization portion 906-1 are only examples, and other relative widths can be used in other examples.

Similarly, the set of drain metal lines of the drain metallization portion 907-1 of the second metallization layer MT2 that extend parallel to one another in the first direction each have a first width, and the additional drain metal line that extends in the second direction perpendicular to the first direction has a second width that is greater than the first width. Again, the particular relative widths shown in the figure for the set of drain metal lines and the additional drain metal line of the drain metallization portion 907-1 are only examples, and other relative widths can be used in other examples. As indicated previously, in some examples, the first width is about 0.3 to 0.5 μm, and the second width is about 2.0 to 7.0 μm.

As shown in FIG. 9, at least a subset of the set of source metal lines of the second metallization layer MT2 are interleaved with at least a subset of the set of drain metal lines of the second metallization layer MT2. Other types of interleaving of source and drain metal lines can be used in other examples.

In the example of FIG. 9, the interleaving of the source and drain metal lines of the second metallization layer serves to increase the current-carrying capacity of the semiconductor device 900 in the previously-described pnp BJT mode of operation. In some examples, a ratio of the amounts of MT2 metallization on source and drain, also referred to as source and drain metal density, is maintained in a one-to-one ratio for balanced current conduction.

Also as shown in FIG. 9, the source and drain metal lines of MT1 and MT2 do not overlap with the gate, in order to significantly reduce the capacitance with respect to the gate (e.g., the capacitances C_{GS} and C_{GD}, depicted in FIG. 3). In some examples, the source and drain metal lines have a minimal width, subject to requirements for establishing corresponding connections to the source and drain, in order to minimize any overlap with the gate. The interleaving arrangement nonetheless allows for the inclusion of wider additional metal lines in MT2 for establishing connections to one or more rings, such as the first, second and third rings 712, 714 and 716 in the example of FIG. 7.

In some examples, at least one doped semiconductor region laterally surrounds the source and drain regions of the semiconductor device 900, and forms at least one ring of the type previously described herein.

In some examples, the gate of the semiconductor device 900 is coupled to an internal node of a circuit, such as an output circuit. The gate and the source and drain regions collectively form a field effect transistor, such as a PMOS device, with the source region coupled to an upper supply terminal VDD of the circuit and the drain region coupled to an output terminal OUT of the circuit.

As described previously, some examples include multiple rings, such as a first ring formed in a well region and having a periphery that laterally surrounds respective peripheries of the source and drain regions, with the first ring being coupled to the upper supply terminal VDD of the circuit, and a second ring having a periphery that laterally surrounds the periphery of the first ring, with the second ring being coupled to the output terminal OUT of the circuit.

In some examples, the second source metal lines of the second metallization layer MT2 illustratively couple the first source metal lines of the first metallization layer MT1 to the first ring. Similarly, the second drain metal lines of the second metallization layer illustratively couple the first drain metal lines of the first metallization layer to the second ring.

Some examples further include a third ring, having a periphery that laterally surrounds the periphery of the second ring, with the third ring being coupled to the upper supply terminal VDD of the circuit. In one or more such examples, the second source metal lines of the second metallization layer MT2 illustratively couple the first source metal lines of the first metallization layer MT1 to the third ring, as well as to the first ring as previously indicated. Again, numerous other arrangements of semiconductor devices and one or more rings can be used in other examples.

As indicated previously, some examples implement a PMOS device with source and drain regions arranged in parallel with one another along a long dimension of the PMOS device, with reduced-width (e.g., minimum design rule width) source and drain metal lines in first and second metallization layers MT1 and MT2, other than the additional source and drain lines of MT2 that extend perpendicular to the reduced-width source and drain metal lines to provide enhanced current-carrying capacity during ESD events of different types. The reduced-width source and drain metal lines advantageously serve to reduce gate-to-source and gate-to-drain capacitances, thereby facilitating the achievement of performance requirements such as those relating to noise, operating speed and other functional specifications. Accordingly, some examples provide improved arrangements of metallization layers that provide reduced gate-to-source and gate-to-drain capacitances while also increasing current-carrying capacity during various types of ESD events.

In some examples of this type, a third metallization layer, illustratively an MT3 layer, is used to route metal lines of the second metallization layer to corresponding pads of an integrated circuit.

Examples described herein provide enhanced ESD protection in output circuits and/or other circuits by implementing PMOS devices or other semiconductor devices with one or more associated rings and/or improved metallization layer arrangements. Such circuits can advantageously provide an area-efficient implementation, with enhanced current-carrying capacity in multiple operating modes responsive to ESD events of different types, while also meeting performance requirements such as noise and operating speed. In some examples, output circuits or other circuits as disclosed herein are able to operate at high speeds (e.g., about 100 Mbps or more) over varying supply voltage conditions.

As indicated previously, such examples provide technical solutions to significant problems of alternative approaches, by overcoming challenges that can otherwise arise in attempting to provide adequate levels of ESD protection for semiconductor devices that are subject to cost, area and/or performance constraints.

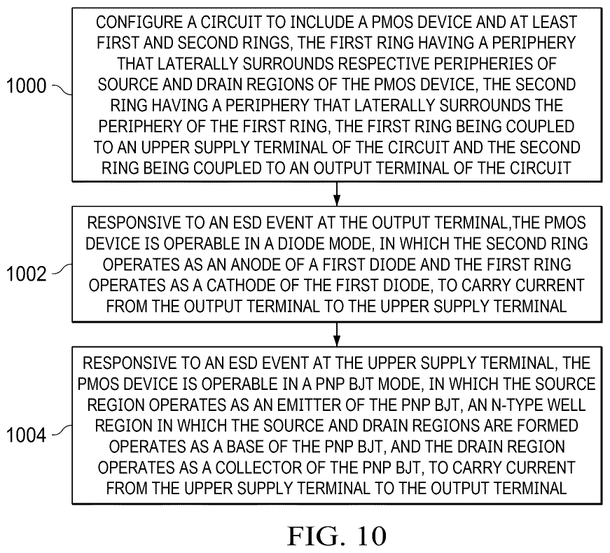

Referring now to FIG. 10, a method of operating an output circuit is shown. The method includes steps 1000, 1002 and 1004, which are illustratively performed with reference to the circuit 101 in the semiconductor device 100 of FIG. 1, although the same or similar steps can be performed relative to other circuits described herein, such as the output circuit in semiconductor device 300 of FIG. 3.

In step 1000, a circuit is configured to include a PMOS device and at least first and second rings, the first ring having a periphery that laterally surrounds respective peripheries of source and drain regions of the PMOS device, the second ring having a periphery that laterally surrounds the periphery of the first ring, with the first ring being coupled to an upper supply terminal of the circuit and the second ring being coupled to an output terminal of the circuit.

Terms such as “configure,” “configured” and “configuring” as used in this context and other similar contexts herein are intended to be broadly construed. For example, a circuit can be illustratively configured as described in step 1000 herein by producing the circuit as described, obtaining the circuit as described, and/or activating the circuit as described at least in part by application of appropriate supply voltages to the circuit.

In step 1002, responsive to an ESD event at the output terminal, the PMOS device is operable in a diode mode, in which the second ring operates as an anode of a first diode and the first ring operates as a cathode of the first diode, to carry current from the output terminal to the upper supply terminal.

In step 1004, responsive to an ESD event at the upper supply terminal, the PMOS device is operable in a pnp BJT mode, in which the source region operates as an emitter of the pnp BJT, an n-type well region in which the source and drain regions are formed operates as a base of the pnp BJT, and the drain region operates as a collector of the pnp BJT, to carry current from the upper supply terminal to the output terminal.

Although shown in serial order, the steps of the FIG. 10 method and other methods described herein need not be performed in the particular order shown. For example, certain steps may be performed at least in part in parallel with one another, and additional or alternative steps may be used in other examples.

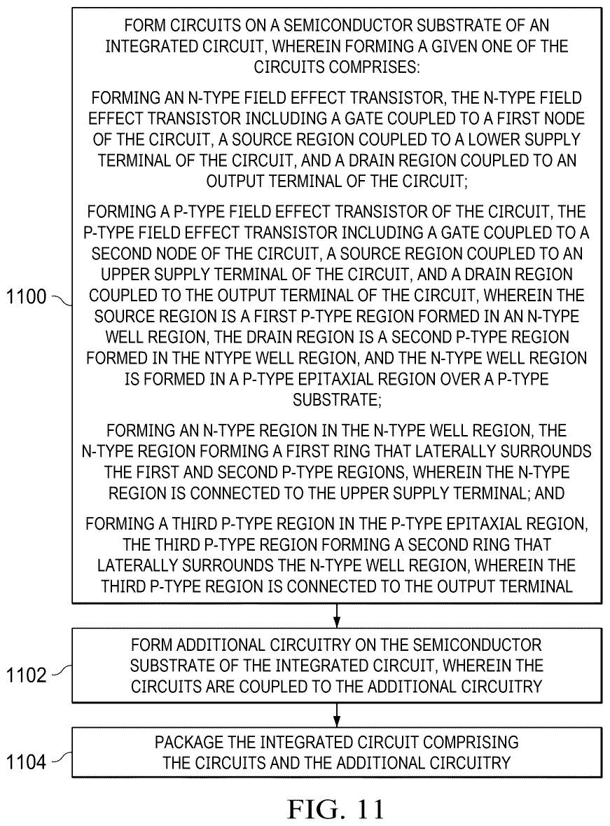

Referring now to FIG. 11, a method of manufacturing an integrated circuit comprising a plurality of circuits is shown. The method includes steps 1100, 1102 and 1104, which are illustratively performed with reference to at least one instance of integrated circuit 200 of FIG. 2, although the same or similar steps can be performed relative to other integrated circuits described herein.

In step 1100, circuits are formed on a semiconductor substrate of an integrated circuit.

Forming a given one of the circuits comprises forming an n-type field effect transistor, the n-type field effect transistor including a gate coupled to a first node of the circuit, a source region coupled to a lower supply terminal of the circuit, and a drain region coupled to an output terminal of the circuit, and forming a p-type field effect transistor, the p-type field effect transistor including a gate coupled to a second node of the circuit, a source region coupled to an upper supply terminal of the circuit, and a drain region coupled to the output terminal of the circuit, wherein the source region is a first p-type region formed in an n-type well region, the drain region is a second p-type region formed in the n-type well region, and the n-type well region is formed in a p-type epitaxial region over a p-type substrate.

Forming the given one of the circuits further comprises forming an n-type region in the n-type well region, the n-type region forming a first ring that laterally surrounds the first and second p-type regions, wherein the n-type region is connected to the upper supply terminal, and forming a third p-type region in the p-type epitaxial region, the third p-type region forming a second ring that laterally surrounds the n-type well region, wherein the third p-type region is connected to the output terminal.

In step 1102, additional circuitry is formed on the semiconductor substrate of the integrated circuit, with the plurality of circuits being coupled to the additional circuitry. For example, the plurality of circuits can comprise one or more of the input circuits 205 and/or one or more of the output circuits 210, and the additional circuitry can comprise additional circuitry 204, as shown in FIG. 2.

Such additional circuitry can be formed at least in part concurrently with the formation of the circuits in step 1100. These formation steps illustratively utilize semiconductor process techniques of the type previously described herein.

In step 1104, the integrated circuit comprising the plurality of circuits and the additional circuitry is packaged. For example, in the case of multiple integrated circuits formed on a semiconductor wafer, individual integrated circuits are diced from the wafer. The individual integrated circuits are then each subject to additional operations such as lead frame attachment, wire bonding and encapsulation, and then packaged in an appropriate package such as a single in-line package (SIP), dual in-line package (DIP), quad flat no-lead (QFN) package, dual flat no-lead (DFN) package, chip-on-lead (COL) package, etc.

Again, although shown in serial order, the steps of the FIG. 11 method need not be performed in the particular order shown. For example, certain steps, such as the steps 1100 and 1102 of forming the respective circuits and additional circuitry, may be performed at least in part in parallel with one another, and additional or alternative steps may be used in other examples.

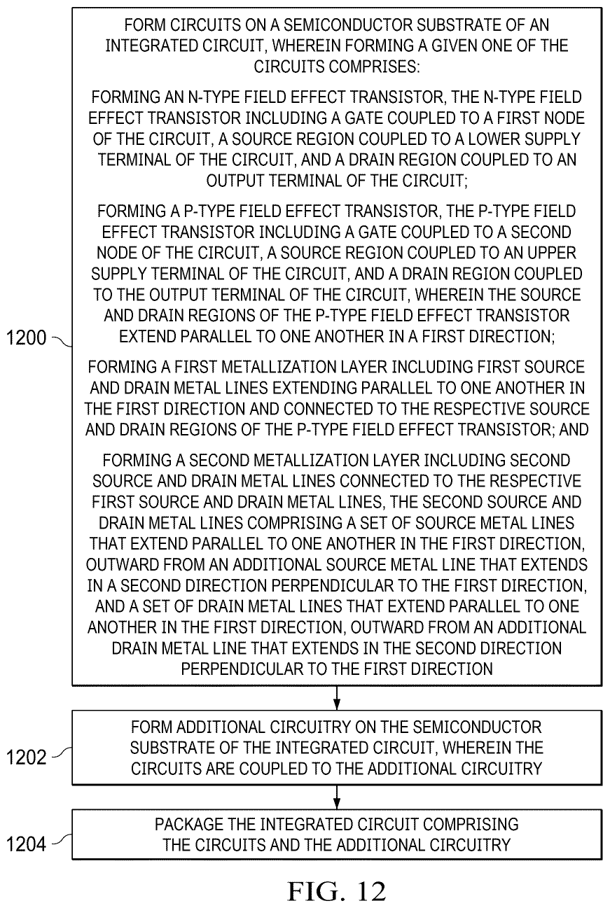

Referring now to FIG. 12, another method of manufacturing an integrated circuit comprising a plurality of circuits is shown. The method includes steps 1200, 1202 and 1204, which are illustratively performed with reference to at least one instance of integrated circuit 200 of FIG. 2, although the same or similar steps can be performed relative to other integrated circuits described herein.

In step 1200, circuits are formed on a semiconductor substrate of an integrated circuit.

Forming a given one of the circuits comprises forming an n-type field effect transistor, the n-type field effect transistor including a gate coupled to a first node of the circuit, a source region coupled to a lower supply terminal of the circuit, and a drain region coupled to an output terminal of the circuit, and forming a p-type field effect transistor of the circuit, the p-type field effect transistor including a gate coupled to a second node of the circuit, a source region coupled to an upper supply terminal of the circuit, and a drain region coupled to the output terminal of the circuit, wherein the source and drain regions of the p-type field effect transistor extend parallel to one another in a first direction.

Forming the given one of the circuits further comprises forming a first metallization layer including first source and drain metal lines extending parallel to one another in the first direction and connected to the respective source and drain regions of the p-type field effect transistor, and forming a second metallization layer including second source and drain metal lines connected to the respective first source and drain metal lines, the second source and drain metal lines comprising a set of source metal lines that extend parallel to one another in the first direction, outward from an additional source metal line that extends in a second direction perpendicular to the first direction, and a set of drain metal lines that extend parallel to one another in the first direction, outward from an additional drain metal line that extends in the second direction perpendicular to the first direction.

In step 1202, additional circuitry is formed on the semiconductor substrate of the integrated circuit, with the plurality of circuits being coupled to the additional circuitry. For example, the plurality of circuits can comprise one or more of the input circuits 205 and/or one or more of the output circuits 210, and the additional circuitry can comprise additional circuitry 204, as shown in FIG. 2.

Such additional circuitry can be formed at least in part concurrently with the formation of the circuits in step 1200. These formation steps illustratively utilize semiconductor process techniques of the type previously described herein.

In step 1204, the integrated circuit comprising the plurality of circuits and the additional circuitry is packaged. For example, in the case of multiple integrated circuits formed on a semiconductor wafer, individual integrated circuits are diced from the wafer. The individual integrated circuits are then each subject to additional operations such as lead frame attachment, wire bonding and encapsulation, and then packaged in an appropriate package such as an SIP, DIP, QFN package, DFN package, COL package, etc.

As indicated previously, steps of methods described to herein need not be performed in the particular order shown. For example, certain steps of FIG. 12, such as the steps 1200 and 1202 of forming the respective circuits and additional circuitry, may be performed at least in part in parallel with one another, and additional or alternative steps may be used in other examples.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a field effect transistor comprising a gate, a source region, and a drain region, the source and drain regions having a first conductivity type formed in a well region of a second conductivity type different than the first conductivity type, wherein the source and drain regions extend parallel to one another in a first direction;
a first metallization layer including first source and drain metal lines extending parallel to one another in the first direction and connected to the respective source and drain regions; and
a second metallization layer including second source and drain metal lines connected to the respective first source and drain metal lines, the second source and drain metal lines comprising:
a set of source metal lines that extend parallel to one another in the first direction, outward from an additional source metal line that extends in a second direction perpendicular to the first direction; and
a set of drain metal lines that extend parallel to one another in the first direction, outward from an additional drain metal line that extends in the second direction perpendicular to the first direction.

2. The semiconductor device of claim 1, wherein the first source and drain metal lines of the first metallization layer do not overlap with the gate of the field effect transistor.

3. The semiconductor device of claim 1, wherein at least a subset of the first source and drain metal lines each have a minimum design rule width.

4. The semiconductor device of claim 1, wherein the second source metal lines of the second metallization layer, other than the additional source metal line, do not overlap with the gate of the field effect transistor.

5. The semiconductor device of claim 1, wherein at least a subset of the second source metal lines of the second metallization layer, other than the additional source metal line, each have a minimum design rule width.

6. The semiconductor device of claim 1, wherein the second drain metal lines of the second metallization layer, other than the additional drain metal line, do not overlap with the gate of the field effect transistor.

7. The semiconductor device of claim 1, wherein at least a subset of the second drain metal lines of the second metallization layer, other than the additional drain metal line, each have a minimum design rule width.

8. The semiconductor device of claim 1, wherein the set of source metal lines that extend parallel to one another in the first direction each have a first width, and the additional source metal line that extends in the second direction perpendicular to the first direction has a second width that is greater than the first width.

9. The semiconductor device of claim 1, wherein the set of drain metal lines that extend parallel to one another in the first direction each have a first width, and the additional drain metal line that extends in the second direction perpendicular to the first direction has a second width that is greater than the first width.

10. The semiconductor device of claim 1, wherein at least a subset of the set of source metal lines of the second metallization layer are interleaved with at least a subset of the set of drain metal lines of the second metallization layer.

11. The semiconductor device of claim 1, further comprising at least one doped semiconductor region that laterally surrounds the source and drain regions, wherein the at least one doped semiconductor region forms at least one ring.

12. The semiconductor device of claim 11, wherein the gate is coupled to an internal node of a circuit that includes the field effect transistor, the source region is coupled to an upper supply terminal of the circuit and the drain region is coupled to an output terminal of the circuit.

13. The semiconductor device of claim 12, wherein the at least one ring comprises at least:
a first ring formed in the well region and having a periphery that laterally surrounds respective peripheries of the source and drain regions, the first ring being coupled to the upper supply terminal of the circuit; and
a second ring having a periphery that laterally surrounds the periphery of the first ring, the second ring being coupled to the output terminal of the circuit.

14. The semiconductor device of claim 13, wherein the at least one ring further comprises a third ring having a periphery that laterally surrounds the periphery of the second ring, the third ring being coupled to the upper supply terminal of the circuit.

15. The semiconductor device of claim 13, wherein the second source metal lines of the second metallization layer couple the first source metal lines of the first metallization layer to the first ring.

16. The semiconductor device of claim 13, wherein the second drain metal lines of the second metallization layer couple the first drain metal lines of the first metallization layer to the second ring.

17. The semiconductor device of claim 13, wherein the field effect transistor is operable in different modes of operation responsive to respective electrostatic discharge (ESD) events of different types, the modes of operation comprising at least:
a diode mode of operation in response to an ESD event at the output terminal, wherein in the diode mode of operation the second ring operates as an anode of a first diode and the first ring operates as a cathode of the first diode to carry current from the output terminal to the upper supply terminal; and
a pnp bipolar junction transistor (BJT) mode of operation in response to an ESD event at the upper supply terminal, wherein in the pnp BJT mode of operation the source region operates as an emitter of the pnp BJT, the well region operates as a base of the pnp BJT, and the drain region operates as a collector of the pnp BJT to carry current from the upper supply terminal to the output terminal.

18. An integrated circuit, comprising:
an n-type field effect transistor of a circuit, the n-type field effect transistor including a gate coupled to a first node of the circuit, a source region coupled to a lower supply terminal of the circuit, and a drain region coupled to an output terminal of the circuit;
a p-type field effect transistor of the circuit, the p-type field effect transistor including a gate coupled to a second node of the circuit, a source region coupled to an upper supply terminal of the circuit, and a drain region coupled to the output terminal of the circuit, wherein the source and drain regions of the p-type field effect transistor extend parallel to one another in a first direction;
a first metallization layer including first source and drain metal lines extending parallel to one another in the first direction and connected to the respective source and drain regions of the p-type field effect transistor; and
a second metallization layer including second source and drain metal lines connected to the respective first source and drain metal lines, the second source and drain metal lines comprising:
a set of source metal lines that extend parallel to one another in the first direction, outward from an additional source metal line that extends in a second direction perpendicular to the first direction; and
a set of drain metal lines that extend parallel to one another in the first direction, outward from an additional drain metal line that extends in the second direction perpendicular to the first direction.

19. The integrated circuit of claim 18, wherein the circuit comprising the n-type field effect transistor and the p-type field effect transistor is one of a plurality of output circuits of an isolator circuit of the integrated circuit, the isolator circuit further including a plurality of input circuits and additional circuitry.

20. The integrated circuit of claim 18, wherein the first source and drain metal lines of the first metallization layer do not overlap with the gate of the p-type field effect transistor.

21. The integrated circuit of claim 18, wherein the second source metal lines of the second metallization layer, other than the additional source metal line, do not overlap with the gate of the p-type field effect transistor.

22. The integrated circuit of claim 18, wherein the second drain metal lines of the second metallization layer, other than the additional drain metal line, do not overlap with the gate of the p-type field effect transistor.

23. A method of manufacturing an integrated circuit, comprising:
forming an n-type field effect transistor of a circuit, the n-type field effect transistor including a gate coupled to a first node of the circuit, a source region coupled to a lower supply terminal of the circuit, and a drain region coupled to an output terminal of the circuit;
forming a p-type field effect transistor of the circuit, the p-type field effect transistor including a gate coupled to a second node of the circuit, a source region coupled to an upper supply terminal of the circuit, and a drain region coupled to the output terminal of the circuit, wherein the source and drain regions of the p-type field effect transistor extend parallel to one another in a first direction;
forming a first metallization layer including first source and drain metal lines extending parallel to one another in the first direction and connected to the respective source and drain regions of the p-type field effect transistor; and
forming a second metallization layer including second source and drain metal lines connected to the respective first source and drain metal lines, the second source and drain metal lines comprising:
a set of source metal lines that extend parallel to one another in the first direction, outward from an additional source metal line that extends in a second direction perpendicular to the first direction; and
a set of drain metal lines that extend parallel to one another in the first direction, outward from an additional drain metal line that extends in the second direction perpendicular to the first direction.
